(19) United States
(12) Patent Application Publication
(10) Pub. No.: US 2025/0194161 A1
(43) Pub. Date: Jun. 12, 2025

(54) BACKSIDE SIGNAL CONTACT AND POWER FORMATION FOR STACKED TRANSISTORS

(71) Applicant: International Business Machines Corporation, Armonk, NY (US)

(72) Inventors: Ruilong Xie, Niskayuna, NY (US); LEI ZHUANG, Ridgefield, CT (US); Shay Reboh, Guilderland, NY (US); James P. Mazza, Saratoga Springs, NY (US)

(21) Appl. No.: 18/530,414

(22) Filed: Dec. 6, 2023

(51) Int. Cl. H01L 29/786; H01L 21/8234; H01L 23/48; H01L 23/528; H01L 27/088; H01L 29/06; H01L 29/08; H01L 29/423; H01L 29/66; H01L 29/775

(52) U.S. Cl. CPC H10D 30/6757; H01L 23/481; H01L 23/5286; H10D 30/014; H10D 30/43; H10D 30/6735; H10D 62/121; H10D 62/151; H10D 64/017; H10D 84/0149; H10D 84/038; H10D 84/83

(57) ABSTRACT

Embodiments of the present disclosure include a semiconductor device having stacked transistors with a bottom transistor below a top transistor, the bottom transistor having a first bottom source/drain region and a second bottom source/drain region. A first backside contact is connected to the first bottom source/drain region and a frontside wiring. A second backside contact is connected to the second bottom source/drain region and a backside power plane. A connection via is formed through the backside power plane to connect a top source/drain region of the top transistor to a backside power rail.

### BACKGROUND

The present invention generally relates to fabrication methods and resulting structures for backside signal contact and power formation for stacked field-effect transistors (SFETs).

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

Transistors with smaller physical dimensions generally have faster processing speeds and greater energy efficiency in comparison to transistors with larger physical dimensions. Further, transistors with smaller physical dimensions allow for a greater transistor density in given physical spaces, which allows for increased performance on smaller devices. However, as the physical dimensions of transistors decrease, space allotted to backside power rail connections and backside signal wires connections also decrease. Transistors that do not have strong and stable connections to the power rails and the signal wires may lose functionality or have reduced performance.

### SUMMARY

Embodiments of the present invention are directed to backside signal contact and power formation for stacked FETs (SFETs). A non-limiting method includes providing stacked transistors having a bottom transistor below a top transistor, the bottom transistor having a first bottom source/drain region and a second bottom source/drain region. The method includes forming a first backside contact connected to the first bottom source/drain region and a frontside wiring and forming a second backside contact connected to the second bottom source/drain region and a backside power plane. The method includes forming a connection via formed through the backside power plane to connect a top source/drain region of the top transistor to a backside power rail.

According to one or more embodiments, a non-limiting method includes providing a first backside contact connected to a first source/drain region of a first transistor and a frontside wiring. The method includes providing a second backside contact connected to another first source/drain region of the first transistor and a backside power plane. The method includes providing a connection via formed through the backside power plane to connect a second source/drain region of a second transistor to a backside power rail, the second transistor being stacked on the first transistor.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, and 1C respectively depict a top view and cross-sectional views of a portion of an integrated circuit (IC) under-fabrication after fabrication operations according to one or more embodiments of the invention;

FIGS. 2A, 2B, and 2C respectively depict a top view and cross-sectional views of a portion of an IC under-fabrication after fabrication operations according to one or more embodiments;

FIGS. 3A, 3B, and 3C respectively depict a top view and cross-sectional views of a portion of an IC under-fabrication after fabrication operations according to one or more embodiments;

FIGS. 4A, 4B, and 4C respectively depict a top view and cross-sectional views of a portion of an IC under-fabrication after fabrication operations according to one or more embodiments;

FIGS. 5A, 5B, and 5C respectively depict a top view and cross-sectional views of a portion of an IC under-fabrication after fabrication operations according to one or more embodiments;

FIGS. 6A, 6B, and 6C respectively depict a top view and cross-sectional views of a portion of an IC under-fabrication after fabrication operations according to one or more embodiments;

FIGS. 7A, 7B, and 7C respectively depict a top view and cross-sectional views of a portion of an IC under-fabrication after fabrication operations according to one or more embodiments;

FIGS. 8A, 8B, and 8C respectively depict a top view and cross-sectional views of a portion of an IC under-fabrication after fabrication operations according to one or more embodiments;

FIGS. 9A, 9B, and 9C respectively depict a top view and cross-sectional views of a portion of an IC under-fabrication after fabrication operations according to one or more embodiments;

FIGS. 10A, 10B, and 10C respectively depict a top view and cross-sectional views of a portion of an IC under-fabrication after fabrication operations according to one or more embodiments;

FIGS. 11A, 11B, and 11C respectively depict a top view and cross-sectional views of a portion of an IC under-fabrication after fabrication operations according to one or more embodiments;

FIGS. 12A, 12B, and 12C respectively depict a top view and cross-sectional views of a portion of an IC under-fabrication after fabrication operations according to one or more embodiments;

FIGS. 13A, 13B, and 13C respectively depict a top view and cross-sectional views of a portion of an IC under-fabrication after fabrication operations according to one or more embodiments;

FIGS. 14A, 14B, and 14C respectively depict a top view and cross-sectional views of a portion of an IC under-fabrication after fabrication operations according to one or more embodiments;

FIG. 15 depicts a flowchart of a method of forming a semiconductor structure according to one or more embodiments of the invention; and

FIG. 16 depicts a flowchart of a method of forming a semiconductor structure according to one or more embodiments of the invention.

### DETAILED DESCRIPTION

One or more embodiments of the present invention relate to back-end-of-line (BEOL) interconnect structures. A semiconductor device includes stacked transistors having a bottom transistor below a top transistor, the bottom transistor including a first bottom source/drain region and a second bottom source/drain region. A first backside contact is connected to the first bottom source/drain region and a frontside wiring. A second backside contact is connected to the second bottom source/drain region and a backside power plane. A connection via is formed through the backside power plane to connect a top source/drain region of the top transistor to a backside power rail.

This provides an improved method and structure of forming dual height backside contacts with backside through vias to accommodate tight backside spacing between power planes and between power and signal wires. Even with transistors having smaller physical dimensions and smaller physical spaces, the unique architecture accommodates the greater transistor density for stacked FETs.

In addition to one or more of the features described above or below, additional features include where a dielectric cap is formed under the first backside contact, the dielectric cap isolating the first backside contact from the backside power plane. This advantageously allows connections for densely packed transistors.

In addition to one or more of the features described above or below, additional features include where the first backside contact and the second backside contact are formed through a portion of a backside interlayer dielectric (ILD) layer, the backside ILD layer being different from the dielectric cap. This advantageously allows connections for densely packed transistors on the semiconductor structure.

In addition to one or more of the features described above or below, additional features include where the connection via is formed through the dielectric cap and the second backside contact. This advantageously allows connections for densely packed transistors on the semiconductor structure.

In addition to one or more of the features described above or below, additional features include where the first and second backside contacts comprise a top dimension and a bottom dimension, the bottom dimension being greater than the top dimension. This advantageously allows connections for densely packed transistors on the semiconductor structure.

In addition to one or more of the features described above or below, additional features include where a deep through via connects the first backside contact to the frontside wiring. This advantageously allows connections for densely packed transistors on the semiconductor structure.

In addition to one or more of the features described above or below, additional features include where a deep through via connects the connection via to the top source/drain region of the top transistor. This advantageously allows connections for densely packed transistors on the semiconductor structure.

In addition to one or more of the features described above or below, additional features include where the backside power plane connects to another backside power rail different from the backside power rail. This advantageously allows connections for densely packed transistors on the semiconductor structure.

In addition to one or more of the features described above or below, additional features include where the connection via has sidewalls formed of a dielectric material. This advantageously allows connections for densely packed transistors on the semiconductor structure.

According to one or more embodiments, a non-limited method includes providing stacked transistors comprising a bottom transistor below a top transistor, the bottom transistor comprising a first bottom source/drain region and a second bottom source/drain region. The method includes forming a first backside contact connected to the first bottom source/drain region and a frontside wiring and forming a second backside contact connected to the second bottom source/drain region and a backside power plane. The method includes forming a connection via through the backside power plane to connect a top source/drain region of the top transistor to a backside power rail.

This provides an improved method and structure of forming dual height backside contacts with backside through vias to accommodate tight backside spacing between power planes and between power and signal wires. Even with transistors having smaller physical dimensions and smaller physical spaces, the unique architecture accommodates the greater transistor density for stacked FETs.

In addition to one or more of the features described above or below, additional features include where a dielectric cap is formed under the first backside contact, the dielectric cap isolating the first backside contact from the backside power plane. This advantageously allows connections for densely packed transistors on the semiconductor structure.

In addition to one or more of the features described above or below, additional features include where the first backside contact and the second backside contact are formed through a portion of a backside interlayer dielectric (ILD) layer, the backside ILD layer being different from the dielectric cap. This advantageously allows connections for densely packed transistors on the semiconductor structure.

In addition to one or more of the features described above or below, additional features include where the connection via is formed through the dielectric cap and the second backside contact. This advantageously allows connections for densely packed transistors on the semiconductor structure.

In addition to one or more of the features described above or below, additional features include where the first and second backside contacts comprise a top dimension and a bottom dimension, the bottom dimension being greater than the top dimension. This advantageously allows connections for densely packed transistors on the semiconductor structure.

In addition to one or more of the features described above or below, additional features include where a deep through via connects the first backside contact to the frontside wiring. This advantageously allows connections for densely packed transistors on the semiconductor structure.

In addition to one or more of the features described above or below, additional features include where a deep through via connects the connection via to the top source/drain region of the top transistor. This advantageously allows connections for densely packed transistors on the semiconductor structure.

In addition to one or more of the features described above or below, additional features include where the backside power plane connects to another backside power rail different from the backside power rail. This advantageously allows connections for densely packed transistors on the semiconductor structure.

In addition to one or more of the features described above or below, additional features include where the connection via has sidewalls formed of a dielectric material. This advantageously allows connections for densely packed transistors on the semiconductor structure.

According to one or more embodiments, a non-limiting method includes providing a first backside contact connected to a first source/drain region of a first transistor and a frontside wiring and providing a second backside contact connected to another first source/drain region of the first transistor and a backside power plane. The method includes providing a connection via formed through the backside power plane to connect a second source/drain region of a second transistor to a backside power rail, the second transistor being stacked on the first transistor.

This provides an improved method and structure of forming dual height backside contacts with backside through vias to accommodate tight backside spacing between power planes and between power and signal wires. Even with transistors having smaller physical dimensions and smaller physical spaces, the unique architecture accommodates the greater transistor density for stacked FETs.

In addition to one or more of the features described above or below, additional features include where a dielectric cap is formed under the first backside contact, the dielectric cap isolating the first backside contact from the backside power plane. This advantageously allows connections for densely packed transistors on the semiconductor structure.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field-effect transistors (NFET) and p-type field-effect transistors (PFET) are two types of complementary MOSFETs. The NFET includes n-doped source and drain junctions and uses electrons as the current carriers. The PFET includes p-doped source and drain junctions and uses holes as the current carriers.

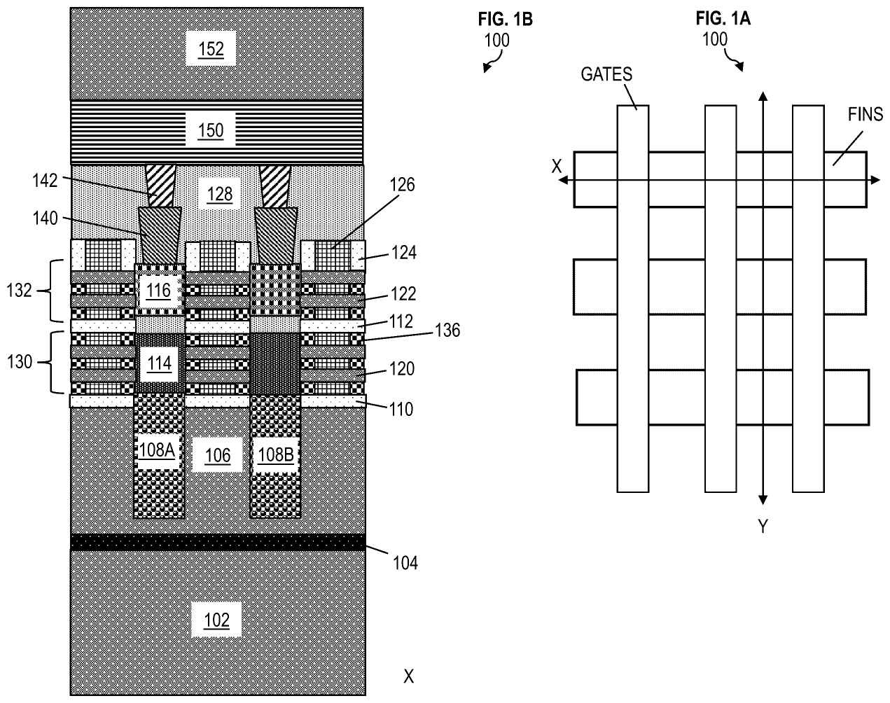

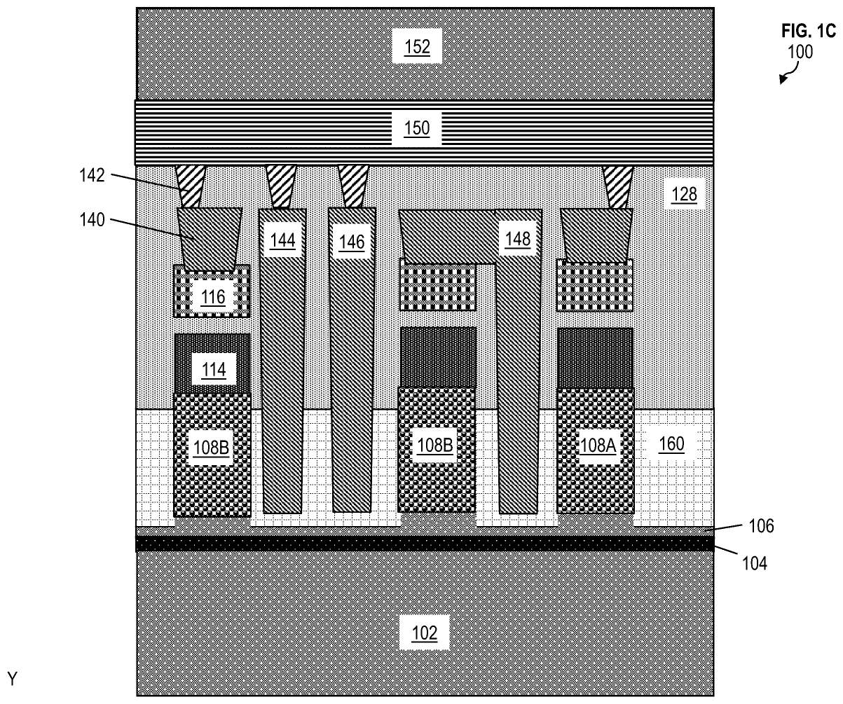

Turning now to a more detailed description of aspects of the present disclosure, FIG. 1A depicts a top view of a simplified illustration of a portion of an integrated circuit (IC) 100, FIG. 1B depicts a cross-sectional view taken along of the IC 100, and FIG. 1C depicts a cross-sectional view taken along Y of the IC 100. For ease of understanding, some layers may be omitted from the various top views so as not to obscure the figure and to view layers underneath. As such, the top view is intended to provide a simplified illustration and a general orientation of a portion of the IC. Standard semiconductor fabrication techniques can be utilized to fabricate the IC as understood by one of ordinary skill in the art. Any suitable lithography processes including deposition techniques and etching techniques can be utilized herein.

FIGS. 1A, 1B, and 1C depict the IC 100 having a wafer where several fabrication processes have been performed. The IC 100 includes stacked transistors having a first transistor 130 and a second transistor 132, where the second transistor 132 is stacked on the first transistor 130. The first transistor 130 is the bottom transistor while the second transistor 132 is the upper transistor. The first transistor 130 and the second transistor 132 are illustrated as nanosheet transistors having gate material 126 wrapping around their respective nanosheets 120 and 122, which serve as the channel regions. The nanosheets 120 and 122 are made of semiconductor materials. Example materials of the nanosheets 120 and 122 can include pure silicon. Other example materials of nanosheets 120 and 122 can include silicon, silicon germanium (SiGe), III-V semiconductors, etc., and dopants can be added as desired to enhance carrier properties. Although nanosheet transistors are illustrated for explanation purposes, one or more embodiments can have other types of stacked transistors.

The first transistor 130 includes source/drain regions 114, while the second transistor 132 includes source/drain regions 116. The first transistor 130 and the second transistor 132 can be complementary transistors where the bottom transistor has p-type source/drain regions resulting in PFETs and the upper transistor has n-type source/drain regions resulting in NFETs, or vice versa. In one or more embodiments, the source/drain regions of the first and second transistors 130 and 132 can be the same, for example, both can be PFETs or both can be NFETs.

A bottom dielectric isolation (BDI) layer 110 separates the first transistor 130 from an upper substrate 106. An etch stop layer 104 separates the upper substrate 106 from a lower substrate 102. Example materials of the etch stop layer 104 can include silicon dioxide, silicon germanium (where, e.g., germanium has a 55 atomic percent and silicon is the remaining atomic percent), etc. A middle dielectric isolation (MDI) layer 112 separates the first transistor 130 from the second transistor 132. Gate spacer material 124 is formed around the gate material 126. The bottom dielectric isolation layer 110, the middle dielectric isolation layer 112, and the gate spacer material 124 can be formed of low-k dielectric material, ultra-low-k dielectric material, etc. Example materials of bottom dielectric isolation layer 110, the middle dielectric isolation layer 112, and the gate spacer material 124 may include silicon carbide (SiC), silicon carbon oxygen (SiCO), SiOCN, SiBCN, etc.

Inner spacers 136 separate the nanosheets 120, bottom dielectric isolation layer 110, middle dielectric isolation layer 112, and nanosheets 122. The inner spacers 136 can be formed of low-k dielectric material, ultra-low-k dielectric material, etc.

Frontside source/drain contacts 140 are formed in interlayer dielectric (ILD) material 128 to be in contact with frontside source/drain regions 116 of the second transistor 132. The frontside source/drain contacts 140 can include tungsten (W), cobalt (Co), gold (Au), copper (Cu), nickel (Ni), cobalt (Co), etc. A silicide may be formed by the deposition of the metal and annealing. Back-end-of-line (BEOL) layer 150 is connected to the frontside source/drain contacts 140 by middle of line (MOL) contacts 142, and a carrier wafer 152 is coupled to the BEOL layer 150. Some of the MOL contacts 142 are in contact with deep metal through vias 144, 146, and 148 that extend to the backside of the IC 100. The MOL contacts 142 and the deep metal through vias 144, 146, and 148 can include tungsten (W), cobalt (Co), gold (Au), copper (Cu), nickel (Ni), cobalt (Co), etc.

Placeholders 108A and 108B are in contact with backside source/drain regions 114 of the first transistor 132 through a shallow trench isolation (STI) layer 160. Example materials of the placeholders 108A and 108B may include intrinsic SiGe.

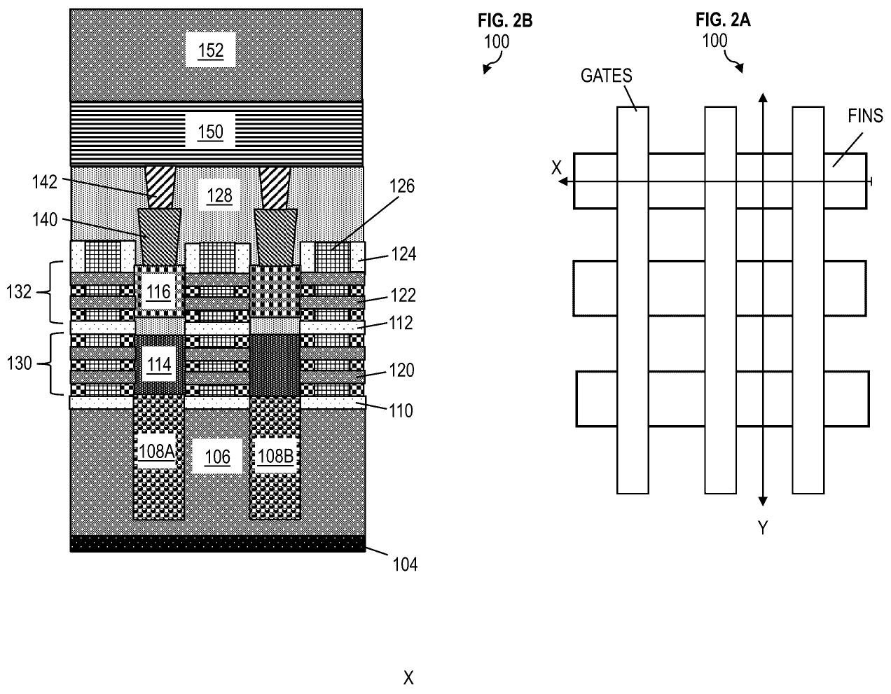

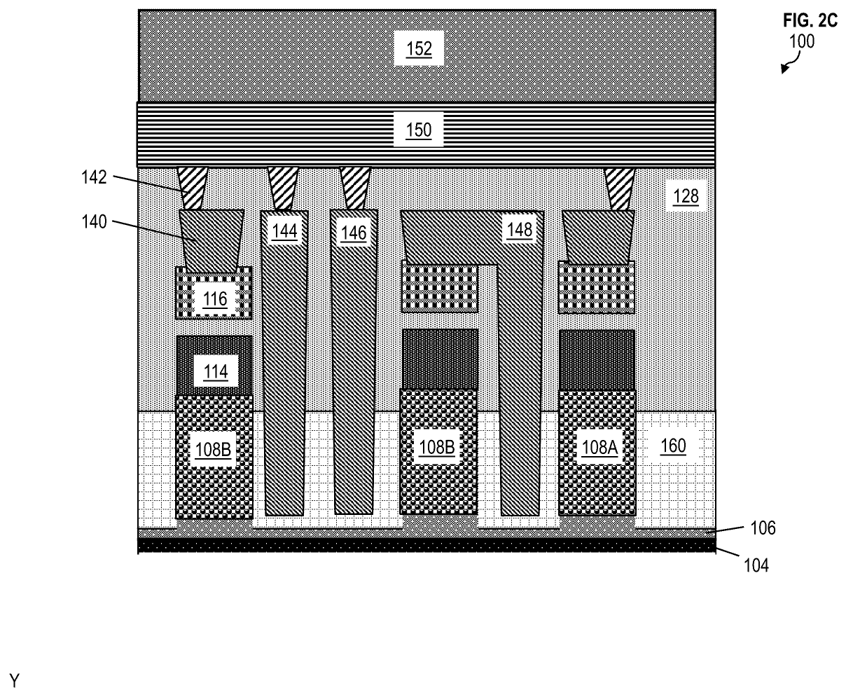

FIGS. 2A, 2B, and 2C depict the IC 100 after wafer flip and substrate removal. To maintain a consistent orientation for the reader, the illustrations of the figures are not flipped. However, it should be understood that wafer is flipped and fabrication operations are being performed on the backside of the wafer. The lower substrate 102 is etched, and the etching stops on the etch stop layer 104.

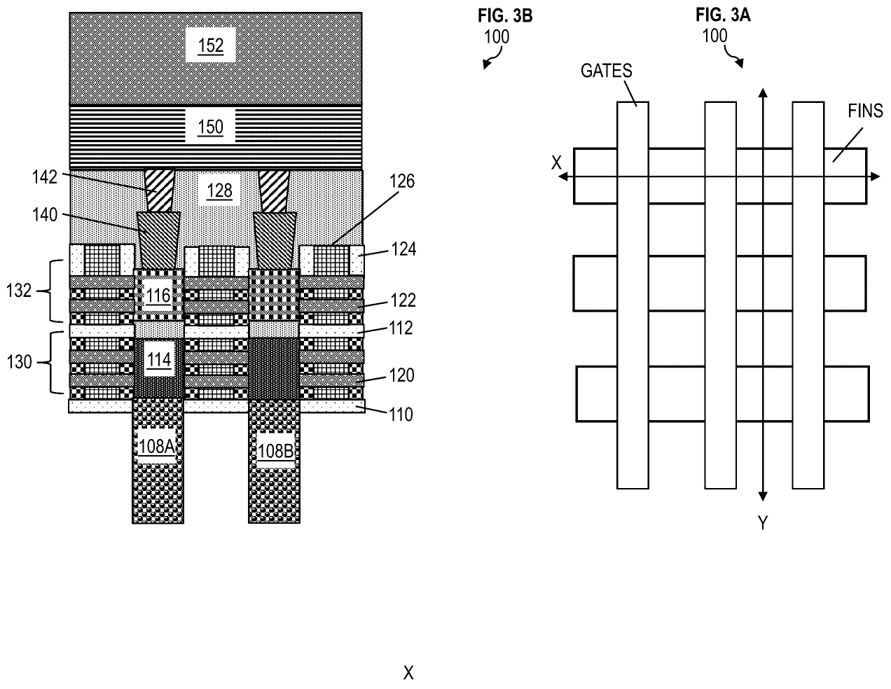

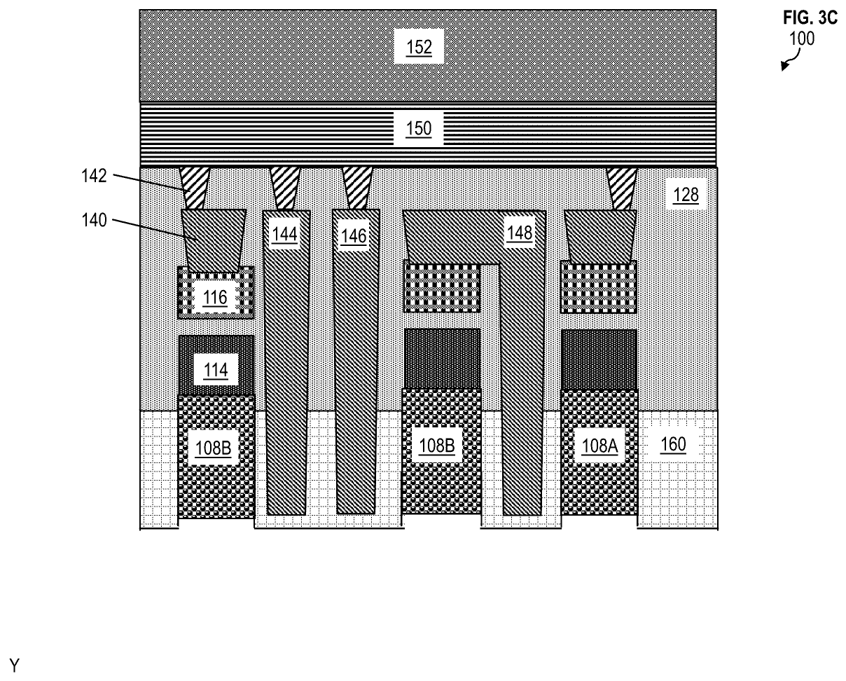

FIGS. 3A, 3B, and 3C depict the IC 100 after removal of the etch stop and removal of the remaining silicon layer. The etch stop layer 104 and upper substrate 106 are etched while leaving the placeholders 108A and 108B.

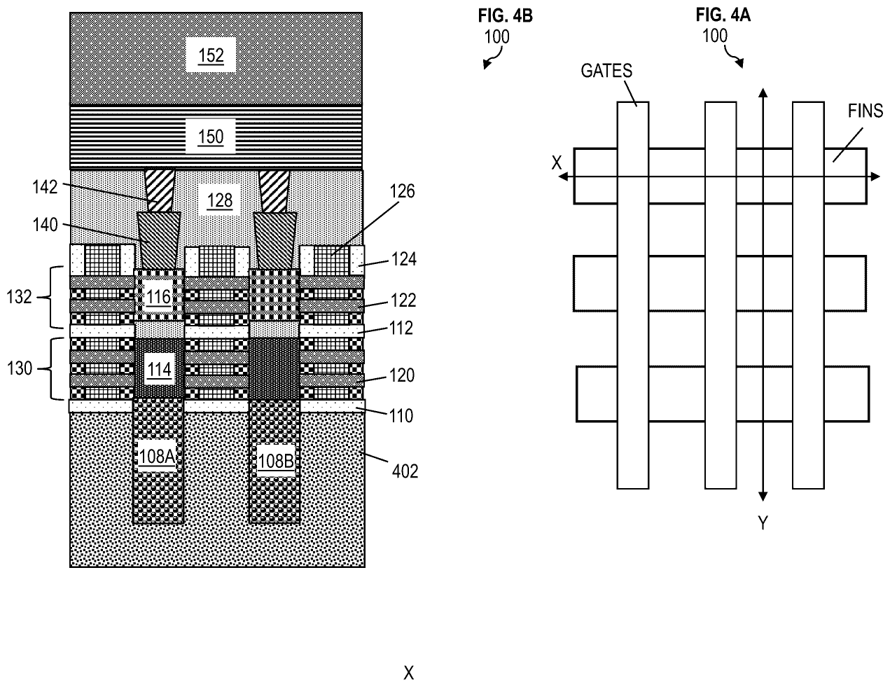

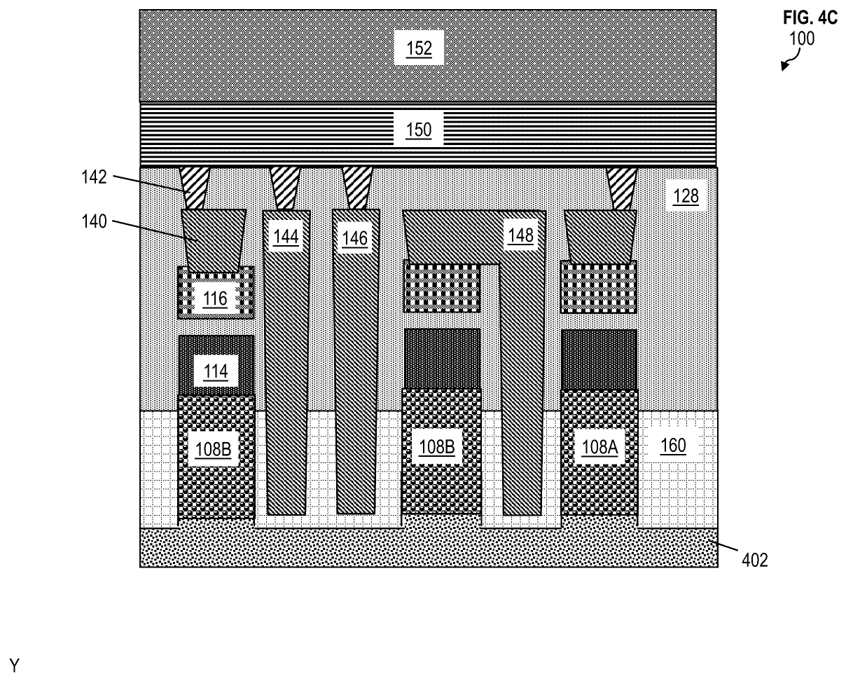

FIGS. 4A, 4B, and 4C depict the IC 100 after deposition of ILD material. Backside ILD material 402 is formed on the backside of the IC 100, thereby covering the exposed portions of the placeholders 108A and 108B and the bottom dielectric isolation layer 110.

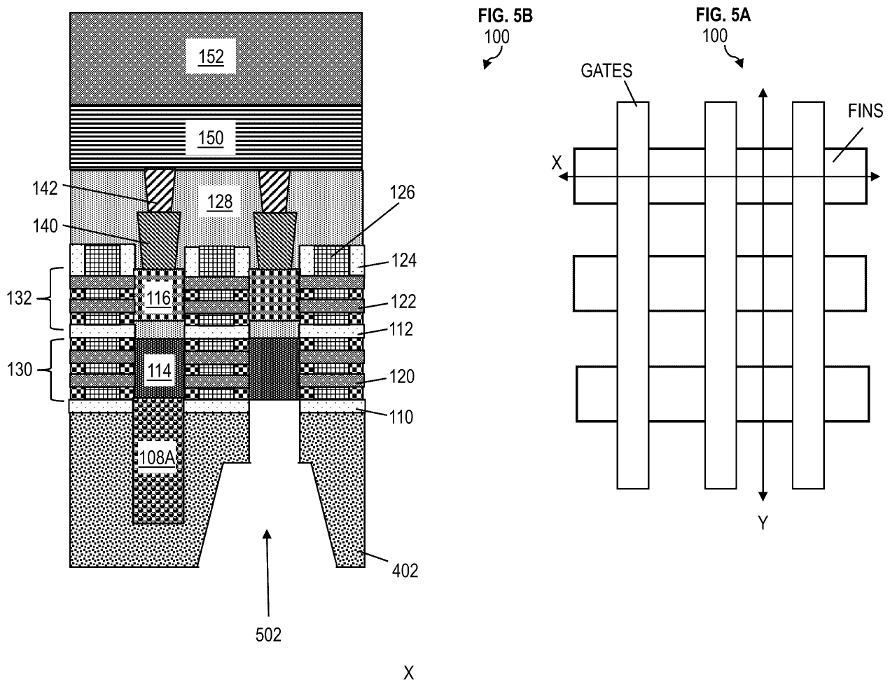

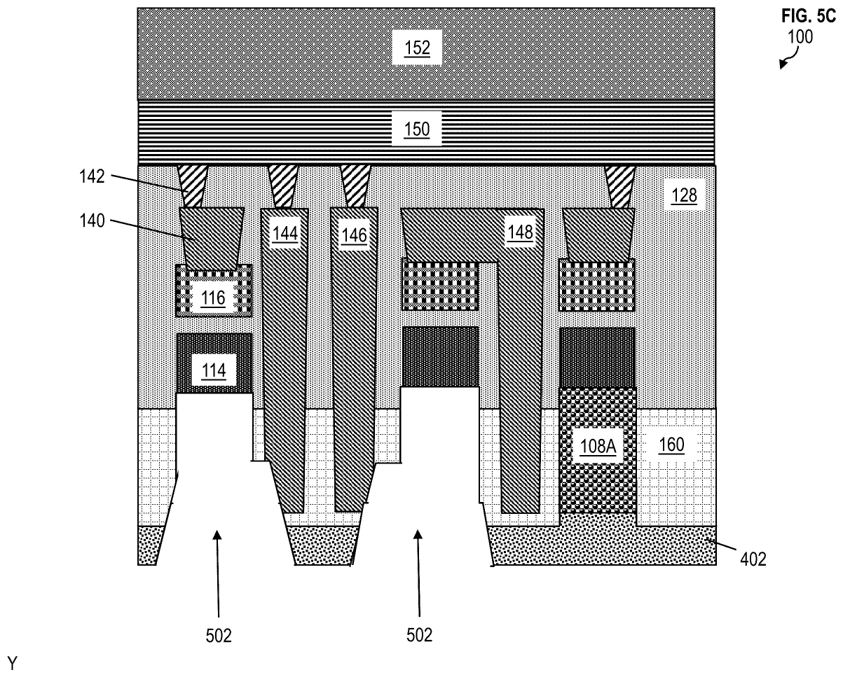

FIGS. 5A, 5B, and 5C depict the IC 100 after backside contact patterning and placeholder removal. Lithography is performed to form trenches 502 in the STI layer 160 and the bottom dielectric isolation layer 110 in preparation for deposition of metal. Etching is performed to remove the placeholders 108B, resulting in the trenches 502. A sidewall of one trench 502 is formed by a portion of the deep through via 144, and a sidewall of another trench 502 is formed by a portion of the deep through via 146. The bottom surfaces of some of the bottom source/drain regions 114 are exposed in preparation for metal contacts. As can be seen, the placeholders 108A remain.

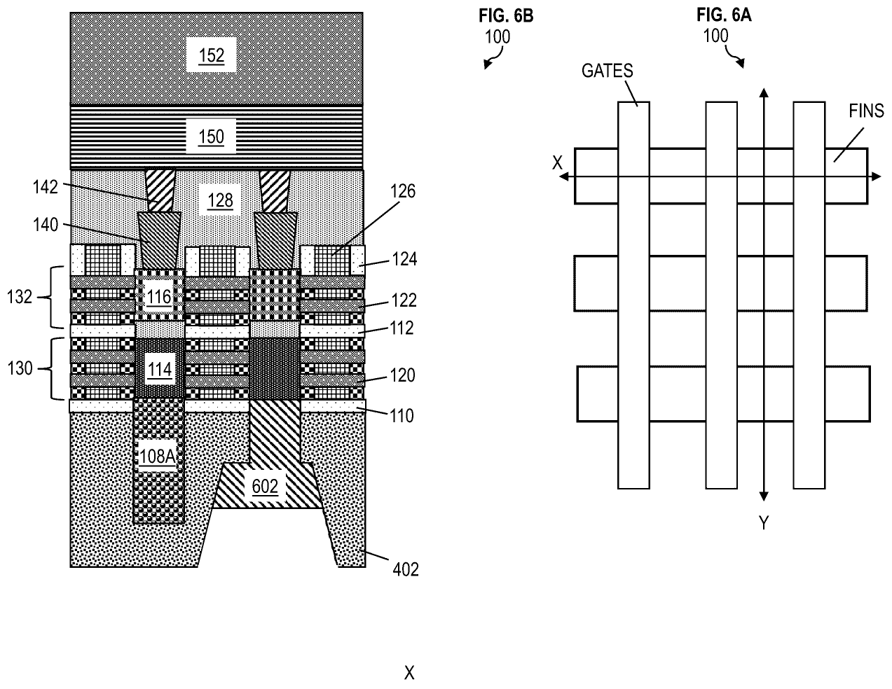

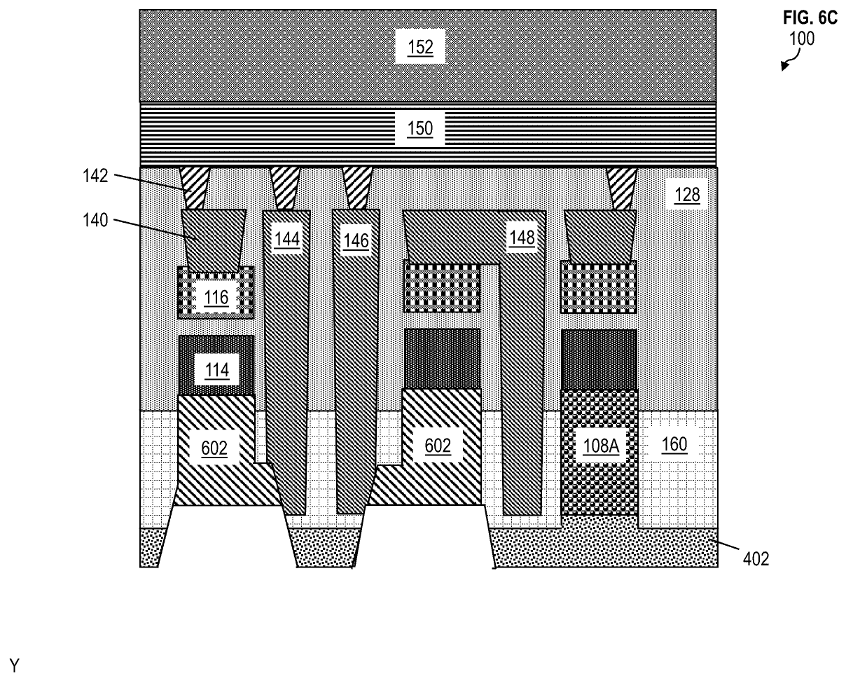

FIGS. 6A, 6B, and 6C depict the IC 100 after metallization. Metal is deposited in the trenches 502 and recessed into first backside contacts 602. Example materials of the first backside contacts 602 can include tungsten (W), cobalt (Co), gold (Au), copper (Cu), nickel (Ni), cobalt (Co), etc. A silicide may be formed by the deposition of the metal and annealing. One first backside contact 602 is electrically shorted to the deep through via 144, and the other first backside contact 602 is electrically shorted to the deep through via 146, as best seen in FIG. 6C.

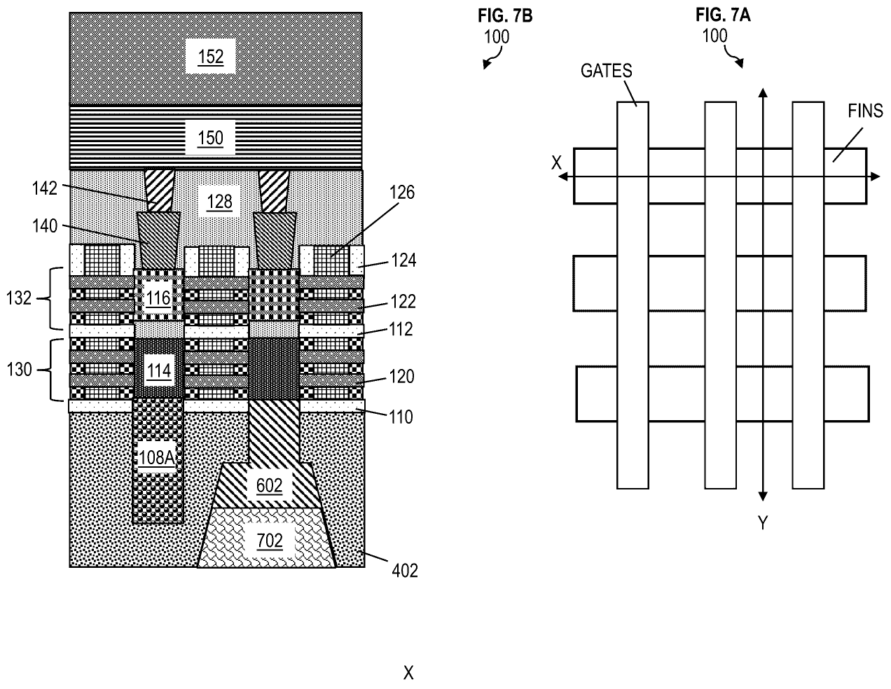

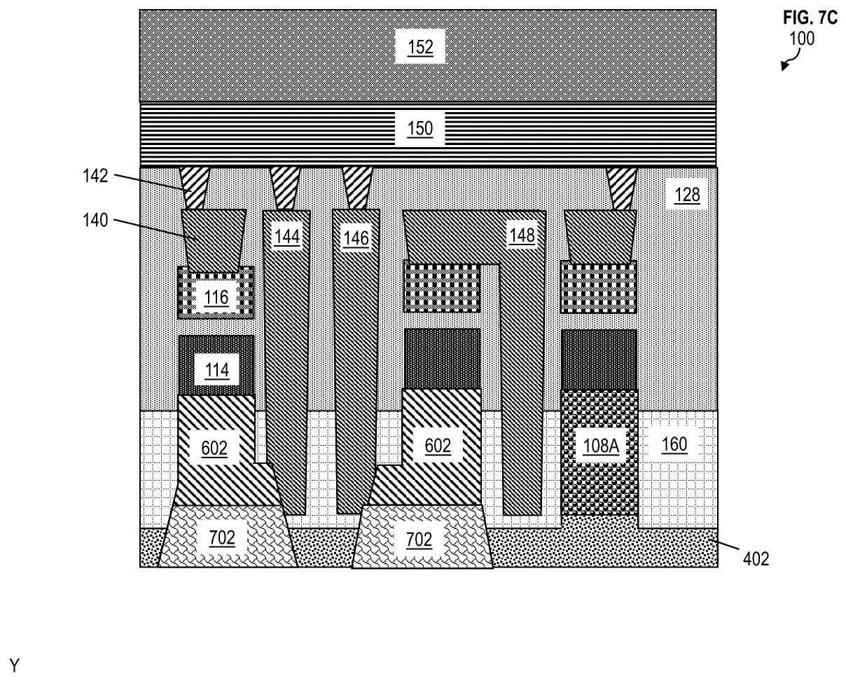

FIGS. 7A, 7B, and 7C depict the IC 100 after deposition of dielectric material. Dielectric material is deposited and planarized to form dielectric caps 702 over the first backside contacts 602. Planarization may be performed to remove excess dielectric material.

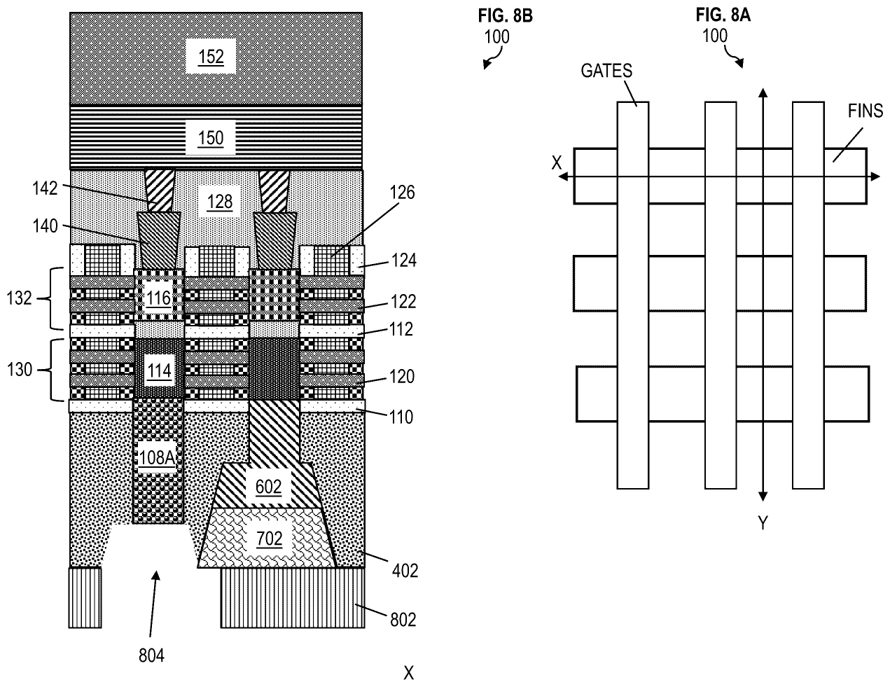

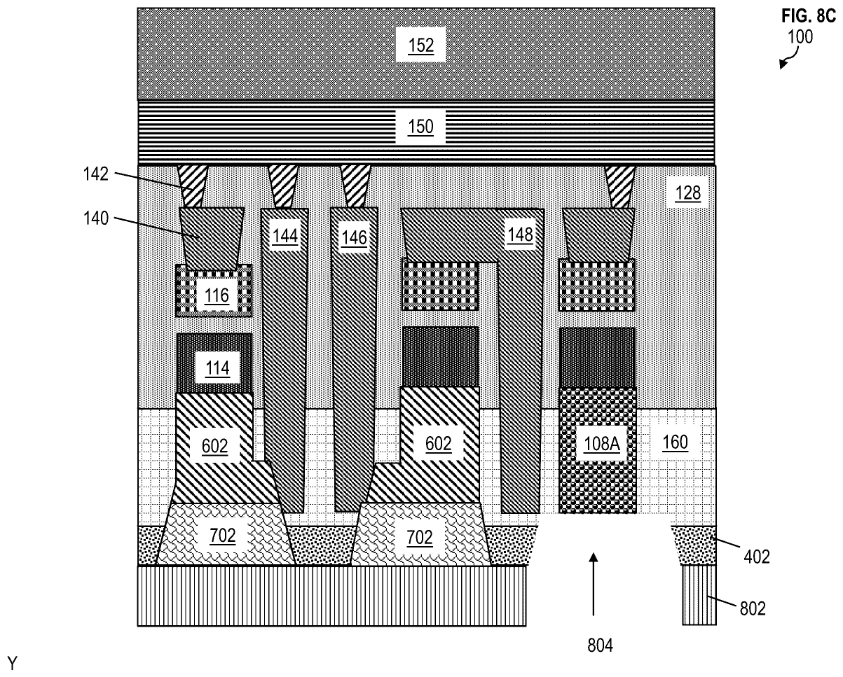

FIGS. 8A, 8B, and 8C depict the IC 100 after backside contact patterning for connection to (VSS) power plane. A photoresist material 802 is deposited and patterned. The photoresist resist material 802 can be an organic planarization layer (OPL). The patterned photoresist material 802 is utilized to etch a trench 804 to expose the placeholder 108A. This is in preparation to remove the placeholder 108A.

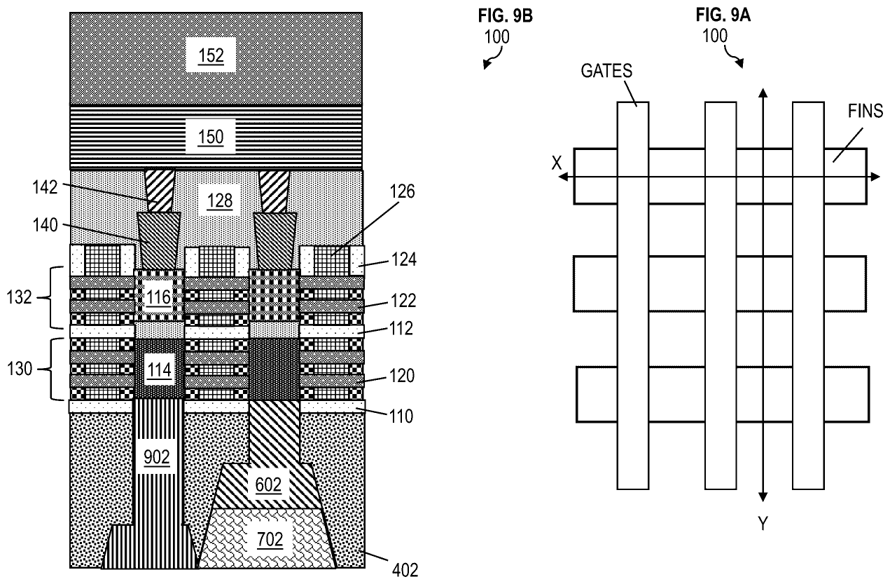

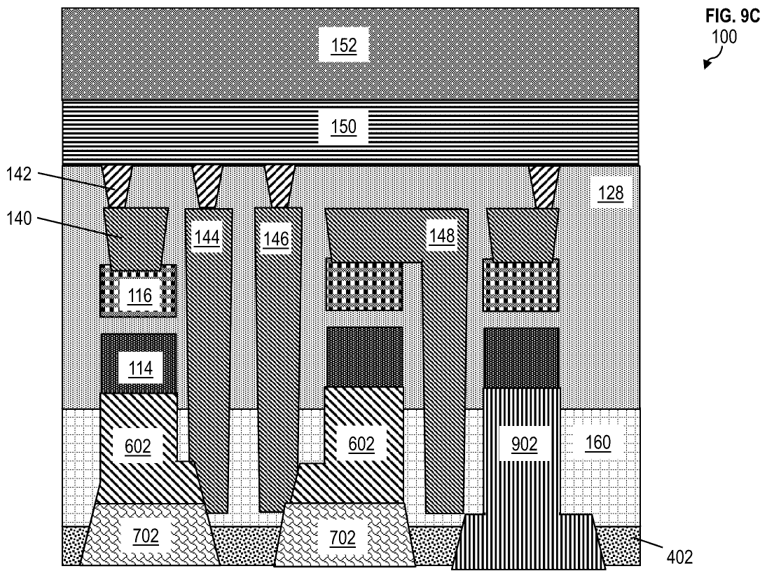

FIGS. 9A, 9B, and 9C depict the IC 100 after placeholder removal and backside contact formation for a (VSS) power plane. The placeholder 108A is removed leaving a trench, and metal is deposited to form a second backside contact 902. Example materials of the second backside contacts 902 can include tungsten (W), cobalt (Co), gold (Au), etc. A silicide may be formed by the deposition of the metal and annealing. The second backside contact 902 is taller or has a greater height than the first backside contact 602. In some cases, the second backside contacts 902 could accidentally be shorted to the deep metal through via 148 because of the tight spacing, but this situation is address by a connection via discussed below.

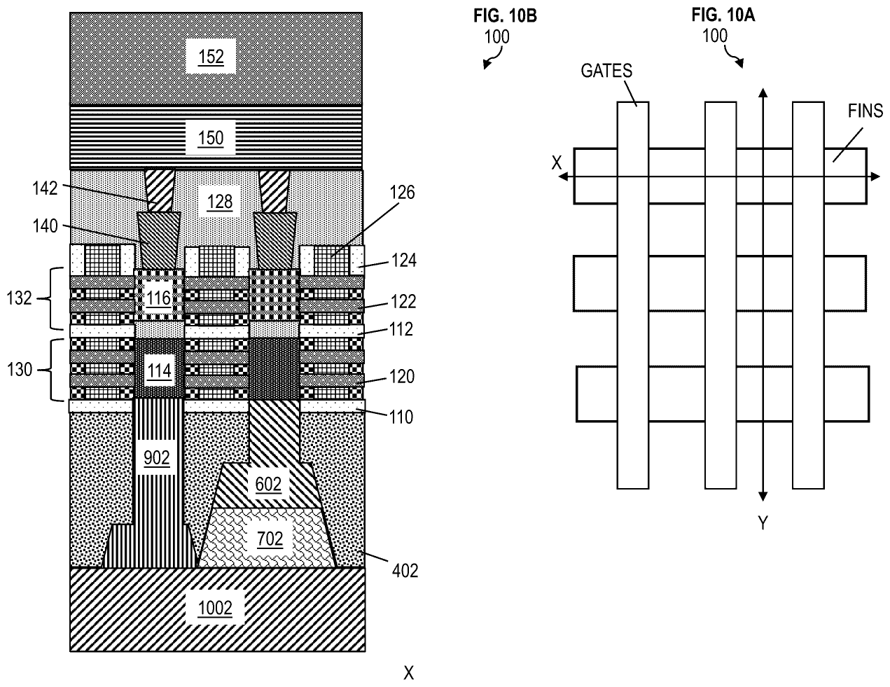

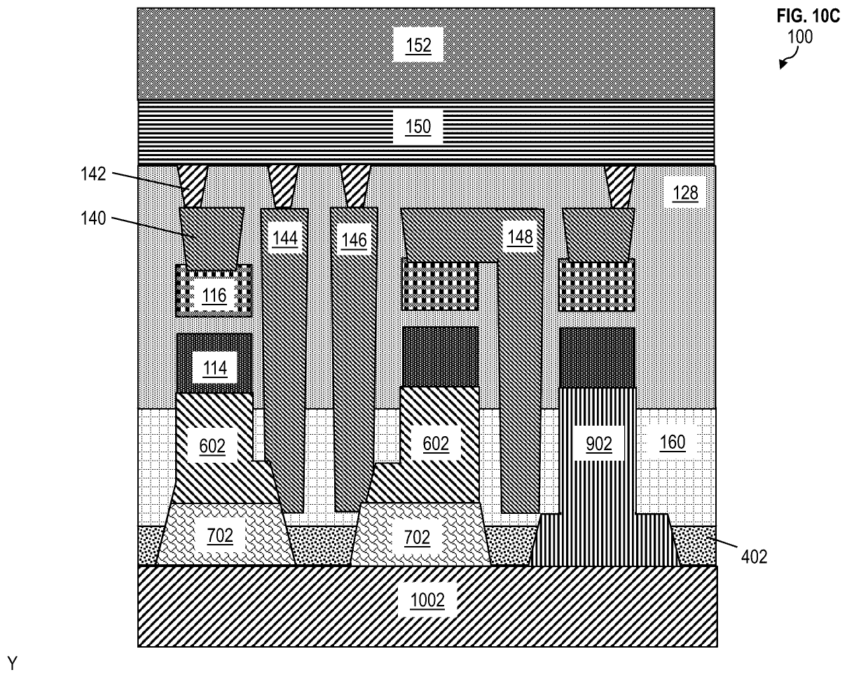

FIGS. 10A, 10B, and 10C depict the IC 100 after forming the (VSS) power plane. A (VSS) power plane 1002 is formed to contact the second backside contact 902 for providing electrical power and to contact the dielectric caps 702. It is noted that the power plane 1002 is seen as a two-dimensional (2D) shape as presently viewed, and the power plane 1002 appears like a plate (not power wires or rails) when viewed from the top down.

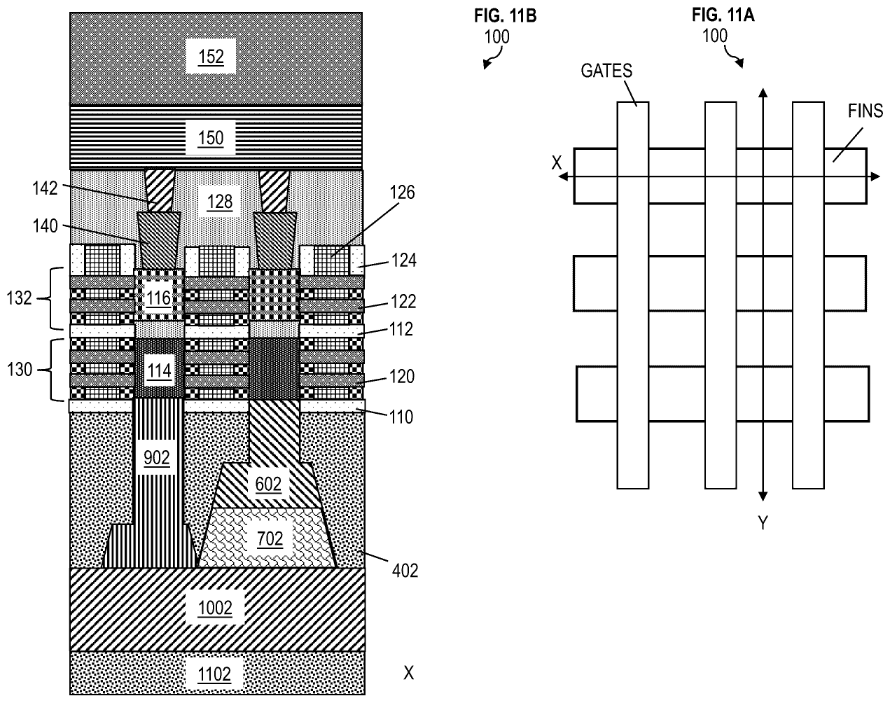

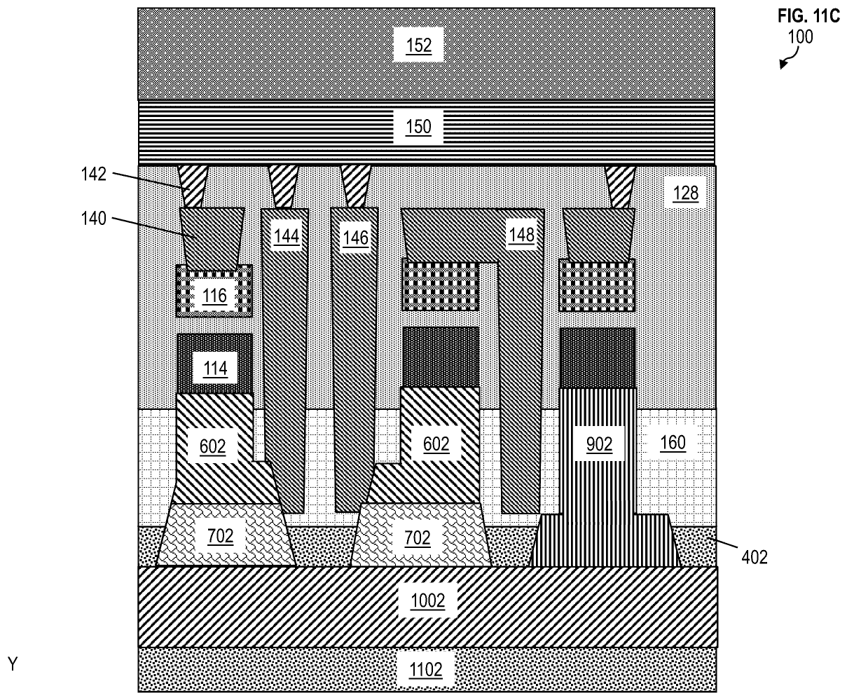

FIGS. 11A, 11B, and 11C depict the IC 100 after forming additional backside ILD. Backside ILD material 1102 is deposited in preparation to open a through via for VDD connection to the deep metal through via 148.

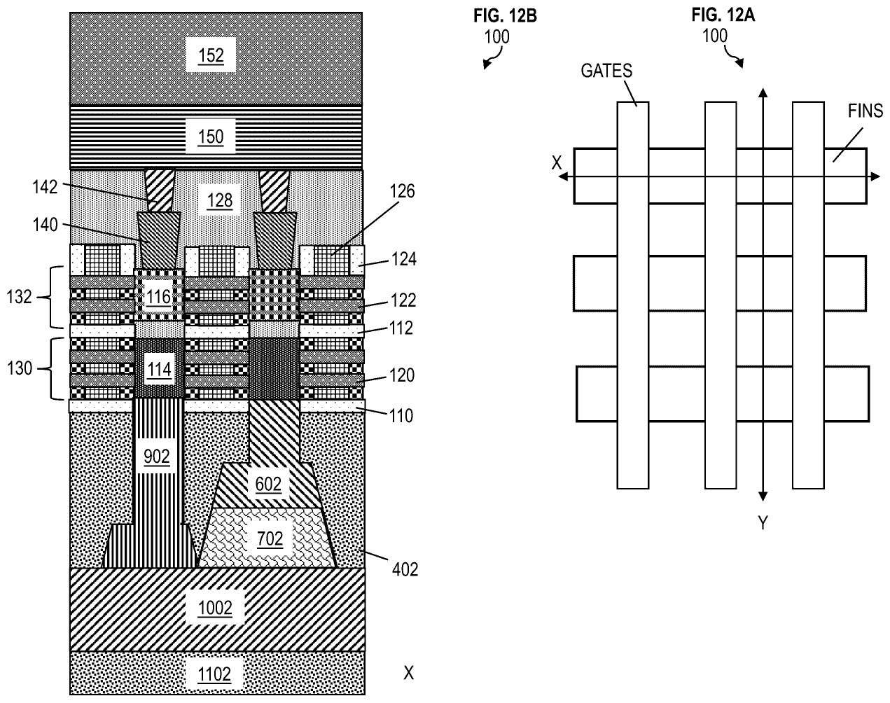

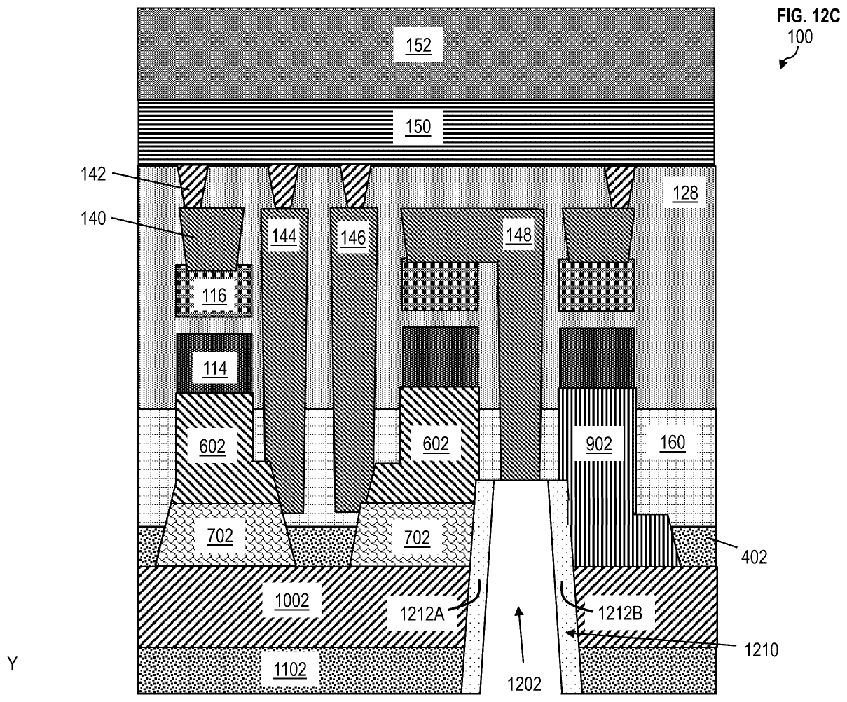

FIGS. 12A, 12B, and 12C depict the IC 100 after forming an opening and adding a sidewall spacer. Lithography is performed to etch trench 1202 through the backside ILD material 1102, through the (VSS) power plane 1002, through the STI layer 160, and through portions the dielectric cap 702, the first backside contact 602, and the second backside contact 902, in order to expose the deep metal through via 148. A portion of the deep metal through via 148 may be etched to ensure a deep trench 1202 that isolates the first backside contact 602, the second backside contact 902, and the deep metal through via 148.

Low-k dielectric material, ultra-low-k dielectric material, etc., is deposited to form sidewalls 1210 on sides of the trench 1202. For explanation, the sidewalls 1210 are further delineated by sidewall 1212A and sidewall 1212B, although the sidewalls 1210 form a continuous layer. The sidewall 1212A insulates the (VSS) power plane 1002 and the first backside contact 602 from a VDD power rail formed later. Similarly, the sidewall 1212B insulates the (VSS) power plane 1002 and the second backside contact 902 from the VDD power rail formed later. It is noted that the sidewalls 1210 (including sidewall 1212A and 1212B) can be high-k dielectric material with a k value>5 or even with a k value>18.

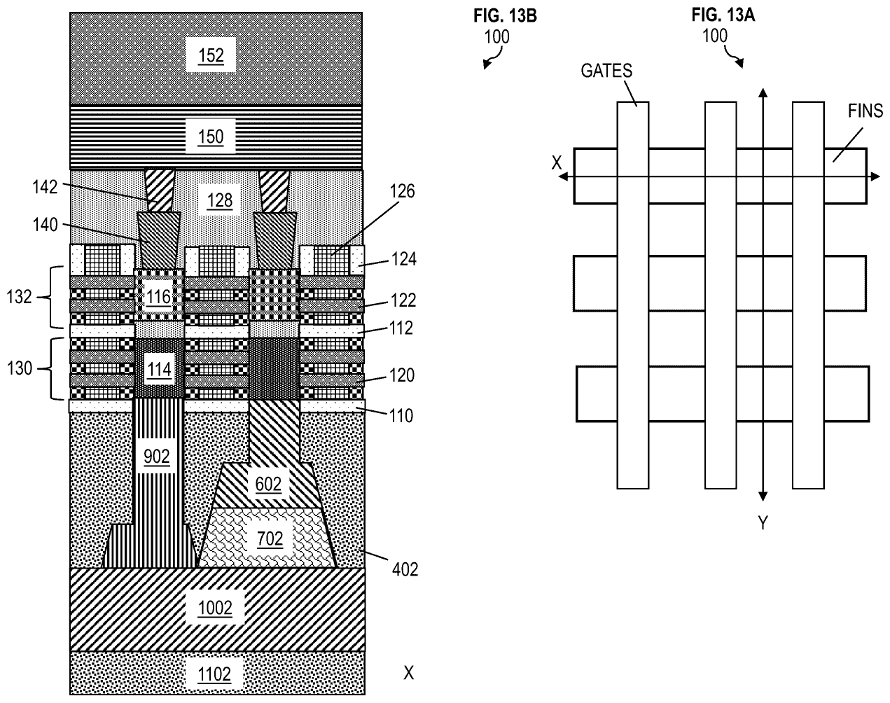

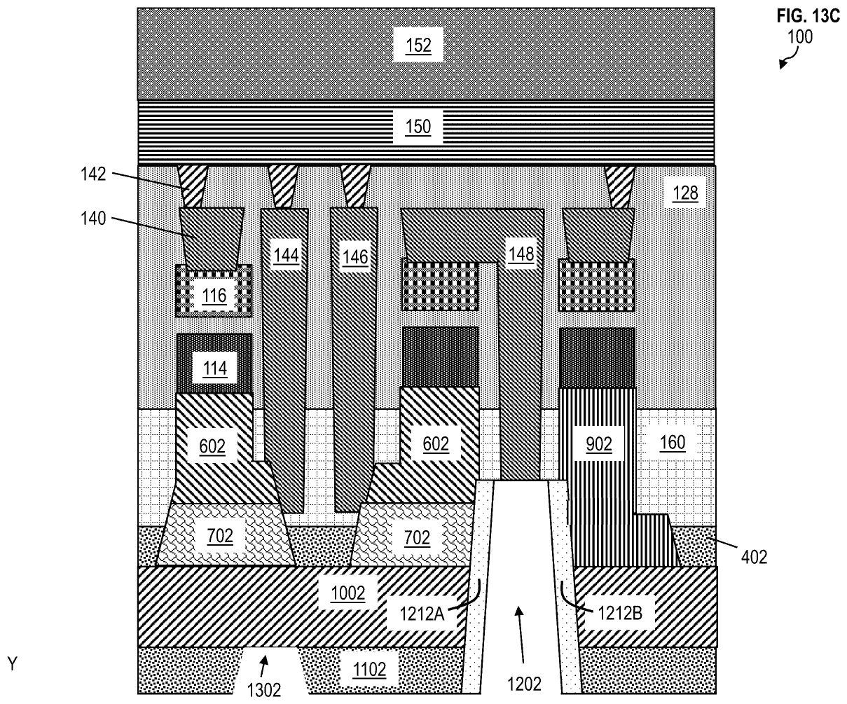

FIGS. 13A, 13B, and 13C depict the IC 100 after formation of a trench for VSS connection. A trench 1302 is formed to expose the (VSS) power plane 1002. The trench 1302 is a normal size cavity compared to the deep trench 1202.

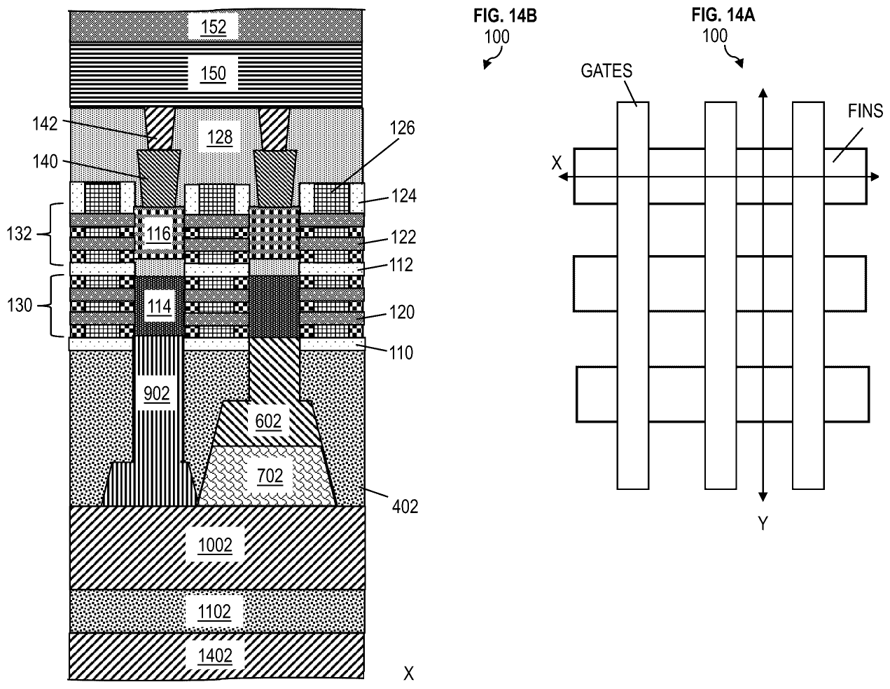

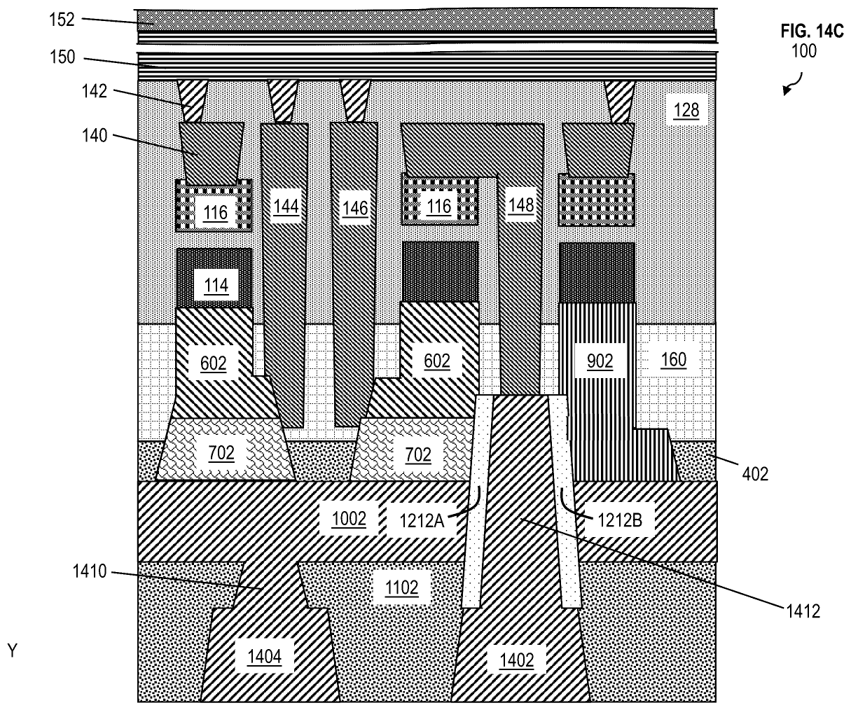

FIGS. 14A, 14B, and 14C depict the IC 100 after metallization. Metallization is performed to form a (VDD) power rail 1402 and a (VSS) power rail 1404. The trench 1302 is filled with metal to form metal via 1410 that connects the (VSS) power plane 1002 to the (VSS) power rail 1404. The trench 1202 is filled with metal to form a connection via 1412 that connects the deep metal through via 148 to the (VDD) power rail 1402.

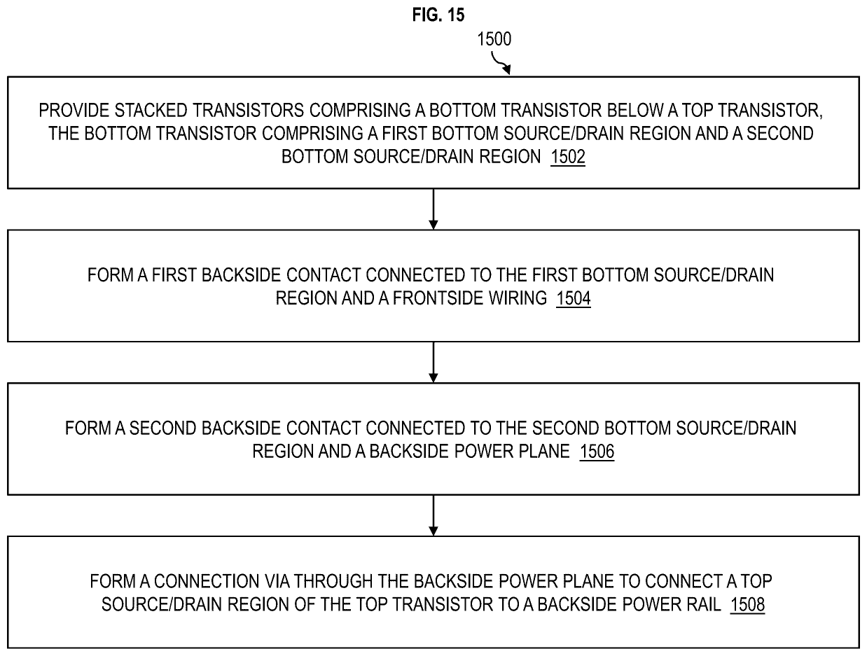

FIG. 15 is a flowchart of a method 1500 of forming backside signal contacts and power formation wires/contacts for stacked field-effect transistors (SFETs) according to one or more embodiments. Reference can be made to any of the figures discussed herein.

At block 1502, the method 1500 includes providing stacked transistors having a bottom transistor (e.g., first transistor 130) below a top transistor (e.g., second transistor 132), the bottom transistor having a first bottom source/drain region (e.g., source/drain region 114) and a second bottom source/drain region (e.g., source/drain region 114). At block 1504, the method 1500 includes forming a first backside contact 602 connected to the first bottom source/drain region (e.g., source/drain region 114) and a frontside wiring (e.g., BEOL layer 150). At block 1506, the method 1500 includes forming a second backside contact 902 connected to the second bottom source/drain region (e.g., source/drain region 114) and a backside power plane (e.g., (VSS) power plane 1002). At block 1508, the method 1500 includes forming a connection via 1412 through the backside power plane (e.g., (VSS) power plane 1002) to connect a top source/drain region (e.g., source/drain region 116) of the top transistor to a backside power rail (e.g., (VDD) power rail 1402).

A dielectric cap 702 is formed under the first backside contact 602, the dielectric cap 702 isolating the first backside contact 602 from the backside power plane (e.g., (VSS) power plane 1002). The first backside contact 602 and the second backside contact 902 are formed through a portion of a backside interlayer dielectric (ILD) layer (e.g., backside ILD material 402), the backside ILD layer being different from the dielectric cap 702.

The connection via 1412 is formed through the dielectric cap 702 and the second backside contact 902. The first and second backside contacts include a top dimension and a bottom dimension, the bottom dimension being greater than the top dimension. A deep through via (e.g., deep metal through vias 144 and 146) connects the first backside contact 602 to the frontside wiring (e.g., BEOL layer 150). A deep through via (e.g., deep metal through via 148) connects the connection via 1412 to the top source/drain region (e.g., source/drain region 116) of the top transistor (e.g., second transistor 132). The backside power plane (e.g., (VSS) power plane 1002) connects to another backside power rail ((VSS) power rail 1404) different from the backside power rail ((VDD) power rail 1402). The connection via 1412 has sidewalls 1210 formed of a dielectric material.

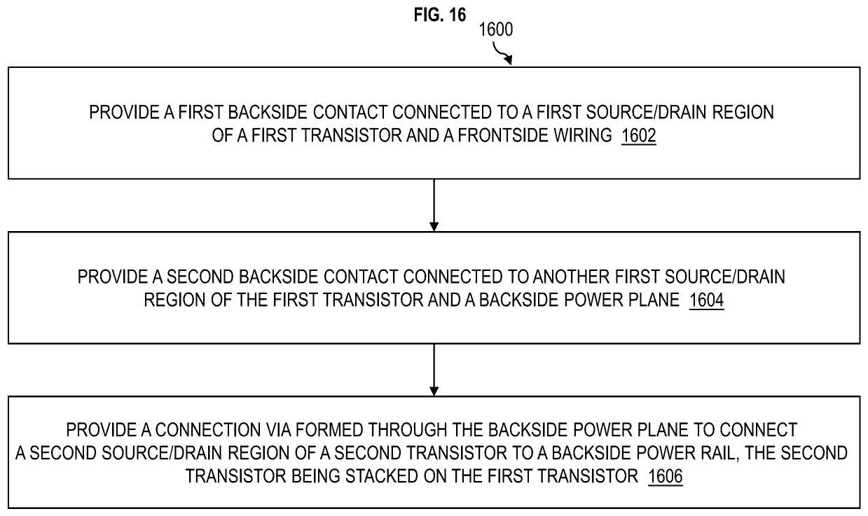

FIG. 16 is a flowchart of a method 1600 of forming backside signal contacts and power formation wires/contacts for stacked field-effect transistors (SFETs) according to one or more embodiments. Reference can be made to any of the figures discussed herein.

At block 1602, the method 1600 includes providing a first backside contact 602 connected to a first source/drain region (e.g., source/drain region 114) of a first transistor (e.g., first transistor 130) and a frontside wiring (e.g., BEOL layer 150). At block 1604, the method 1600 includes providing a second backside contact 902 connected to another first source/drain region (e.g., source/drain region 114) of the first transistor and a backside power plane (e.g., (VSS) power plane 1002). At block 1606, the method 1600 includes providing a connection via 1412 formed through the backside power plane (e.g., (VSS) power plane 1002) to connect a second source/drain region (e.g., source/drain region 116) of a second transistor 132 to a backside power rail ((VDD) power rail 1402), the second transistor 132 being stacked on the first transistor 130.

A dielectric cap 702 is formed under the first backside contact 602, the dielectric cap 702 isolating the first backside contact from the backside power plane (e.g., (VSS) power plane 1002).

In one or more embodiments, the ILD material can be SiO2, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device comprising:
stacked transistors comprising a bottom transistor below a top transistor, the bottom transistor comprising a first bottom source/drain region and a second bottom source/drain region;
a first backside contact connected to the first bottom source/drain region and a frontside wiring;
a second backside contact connected to the second bottom source/drain region and a backside power plane; and
a connection via formed through the backside power plane to connect a top source/drain region of the top transistor to a backside power rail.

2. The semiconductor device of claim 1, wherein a dielectric cap is formed under the first backside contact, the dielectric cap isolating the first backside contact from the backside power plane.

3. The semiconductor device of claim 2, wherein the first backside contact and the second backside contact are formed through a portion of a backside interlayer dielectric (ILD) layer, the backside ILD layer being different from the dielectric cap.

4. The semiconductor device of claim 2, wherein the connection via is formed through the dielectric cap and the second backside contact.

5. The semiconductor device of claim 1, wherein the first and second backside contacts comprise a top dimension and a bottom dimension, the bottom dimension being greater than the top dimension.

6. The semiconductor device of claim 1, wherein a deep through via connects the first backside contact to the frontside wiring.

7. The semiconductor device of claim 1, wherein a deep through via connects the connection via to the top source/drain region of the top transistor.

8. The semiconductor device of claim 1, wherein the backside power plane connects to another backside power rail different from the backside power rail.

9. The semiconductor device of claim 1, wherein the connection via has sidewalls formed of a dielectric material.

10. A method comprising:
providing stacked transistors comprising a bottom transistor below a top transistor, the bottom transistor comprising a first bottom source/drain region and a second bottom source/drain region;
forming a first backside contact connected to the first bottom source/drain region and a frontside wiring;
forming a second backside contact connected to the second bottom source/drain region and a backside power plane; and
forming a connection via through the backside power plane to connect a top source/drain region of the top transistor to a backside power rail.

11. The method of claim 10, wherein a dielectric cap is formed under the first backside contact, the dielectric cap isolating the first backside contact from the backside power plane.

12. The method of claim 11, wherein the first backside contact and the second backside contact are formed through a portion of a backside interlayer dielectric (ILD) layer, the backside ILD layer being different from the dielectric cap.

13. The method of claim 11, wherein the connection via is formed through the dielectric cap and the second backside contact.

14. The method of claim 10, wherein the first and second backside contacts comprise a top dimension and a bottom dimension, the bottom dimension being greater than the top dimension.

15. The method of claim 10, wherein a deep through via connects the first backside contact to the frontside wiring.

16. The method of claim 10, wherein a deep through via connects the connection via to the top source/drain region of the top transistor.

17. The method of claim 10, wherein the backside power plane connects to another backside power rail different from the backside power rail.

18. The method of claim 10, wherein the connection via has sidewalls formed of a dielectric material.

19. A method comprising:
providing a first backside contact connected to a first source/drain region of a first transistor and a frontside wiring;
providing a second backside contact connected to another first source/drain region of the first transistor and a backside power plane; and
providing a connection via formed through the backside power plane to connect a second source/drain region of a second transistor to a backside power rail, the second transistor being stacked on the first transistor.

20. The method of claim 19, wherein a dielectric cap is formed under the first backside contact, the dielectric cap isolating the first backside contact from the backside power plane.
